(19) United States
(12) Patent Application Publication
(10) Pub. No.: US 2013/0343125 A1
(43) Pub. Date: Dec. 26, 2013

(54) APPARATUS AND METHODS FOR CARRYING OUT OPERATIONS IN A NON-VOLATILE MEMORY CELL HAVING MULTIPLE MEMORY STATES

(71) Applicant: MOSAID TECHNOLOGIES INCORPORATED, Ottawa (CA)

(72) Inventors: Peter GILLINGHAM, Ottawa (CA); Jin-Ki KIM, Kanata (CA)

(73) Assignee: MOSAID TECHNOLOGIES INCORPORATED, Ottawa (CA)

(21) Appl. No.: 13/799,765

(22) Filed: Mar. 13, 2013

Related U.S. Application Data
(60) Provisional application No. 61/663,081, filed on Jun. 22, 2012.

(51) Int. Cl. G11C 16/10

(52) U.S. Cl. CPC G11C 16/10
USPC 365/185.03

(57) ABSTRACT

Apparatus and methods for carrying out operations in a non-volatile memory cell having multiple memory states are disclosed. One of the methods is a method for programming N bits in a non-volatile memory cell configured to store up to N+1 bits, where N is an integer greater than zero. The method for programming includes programming N bits of data in the cell. The method for programming also includes programming an additional bit of data that is a logical function of the N bits of data in the cell. The cell is configured to provide 2N+1 threshold voltage ranges for bit storage and, in accordance with the logical function: i) a first set of 2N threshold voltage ranges of the 2N+1 threshold voltage ranges are used to store the N bits of data; and ii) a remaining second set of 2N threshold voltage ranges alternating with the first set are unused.

### CROSS REFERENCE TO RELATED APPLICATIONS

This application claims the benefit of the filing of U.S. Provisional patent application 61/663,081 filed on Jun. 22, 2012 and entitled “METHOD, DEVICE, APPARATUS, AND SYSTEMS FOR STORING DATA IN A MULTIPLE-BIT-PER-CELL (MBC) FLASH”, which is incorporated herein by reference in its entirety.

### BACKGROUND OF THE DISCLOSURE

Non-volatile computer memory is an electronic memory capable of retaining stored information when no power is supplied to the memory. Non-volatile flash memory uses a plurality of memory cells to store information as a charge. The memory cells may be configured as, for example, NAND flash of NOR flash, which while utilizing generally similar memory cells, have different internal configurations and differ somewhat in operation.

NAND flash memory may be configured as a so-called Single Level Cell (SLC) in which a single binary digit (bit) is stored in a memory cell comprising a floating gate transistor, which may be configured in one of two discrete threshold voltage levels representing the single bit of stored information. NAND flash memory may also be configured as a multi-level cell (MLC) in which two or more bits are stored as four or more discrete threshold voltage levels.

While many NAND flash devices manufactured today are configured as to store multiple bits in a cell, there remain applications for which single bit storage in each cell is advantageous. For storing multiple bits in a cell, multiple threshold voltage ranges are defined and these voltage ranges are generally more closely spaced than voltage ranges in single bit per cell memories. Accordingly, multiple bit per cell memories are more susceptible to errors due to sensing noise, cell-to-cell disturbance, and charge loss. Also, multiple bit per cell memories generally have lower endurance as expressed in the number of program and erase (P/E) cycles that can be successfully executed. For example, single bit per cell memories may endure about 100,000 P/E cycles while multiple bit per cell memories may only endure about 5,000 or fewer P/E cycles.

NAND flash configured as single bit per cell or multiple bit per cell memories may have the same basic design and merely configure the memory for either single bit per cell or multiple bits per cell in the final stages of manufacturing, for example through metal masking or wire bonding operations. A NAND flash memory configured for single bit per cell operation would generally have about half or less of the memory capacity of a multiple bit per cell memory implemented using the same manufacturing technology and having the same silicon area. On the other hand, present manufacturing volumes of multiple bit per cell memories far exceeds single bit per cell memories, and the cost of single bit per cell memories on a price per bit basis is significantly higher than the cost of multiple bit per cell memories.

### SUMMARY

In accordance with one aspect of the invention there is provided a method for programming N bits in a non-volatile memory cell configured to store up to N+1 bits, where N is an integer greater than zero. The method includes programming N bits of data in the non-volatile memory cell. The method also includes programming an additional bit of data that is a logical function of the N bits of data in the non-volatile memory cell. The non-volatile memory cell is configured to provide 2^{N+1} threshold voltage ranges for bit storage and, in accordance with the logical function: i) a first set of 2^{N} threshold voltage ranges of the 2^{N+1} threshold voltage ranges are used to store the N bits of data; and ii) a remaining second set of 2^{N} threshold voltage ranges alternating with the first set are unused.

In accordance with another aspect of the invention there is provided a memory device that includes a plurality of non-volatile memory cells. Each non-volatile memory cell of the non-volatile memory cells is configured to provide 2^{N+1} threshold voltage ranges for bit storage, where N is an integer greater than zero. The 2^{N+1} threshold voltage ranges includes an erase voltage range and a plurality of program voltage ranges. The plurality of program voltage ranges including a first program voltage range adjacent to the erase voltage range and a plurality of higher program voltage ranges. The non-volatile memory cell is configured to store up to N+1 bits and the memory device is configured to: a) program N bits of data in the non-volatile memory cell; and b) program an additional bit of data that is a logical function of the N bits of data in the non-volatile memory cell. In accordance with the logical function: i) a first set of 2^{N} threshold voltage ranges of the 2^{N+1} threshold voltage ranges are used to store the N bits of data; and ii) a remaining second set of 2^{N} threshold voltage ranges alternating with the first set are unused.

In accordance with another aspect of the invention there is provided a method carried out in a memory device having a plurality of non-volatile memory cells. Each non-volatile memory cell of the non-volatile memory cells has multiple memory states being defined by respective threshold voltage ranges including an erase voltage range, a first program voltage range, a second program voltage range and a third program voltage range. The first program voltage range is adjacent to the erase voltage range and the second program voltage range is in-between the first and third program voltage ranges. When the non-volatile memory cell is operated in a two bit storage mode, two bits of data are stored by: carrying out a first stage programming to program a first of two bits of data; and, carrying out a second stage programming to program a second of the two bits of data. When the non-volatile memory cell is operated in a one bit storage mode, a single bit of data is stored by: carrying out both the first and second stage programmings in a manner that raises a cell threshold voltage twice to reach the second program voltage range if the single bit of data is data “1”, and keeping the cell threshold voltage at the erase voltage range if the single bit of data is data “0”.

In accordance with another aspect of the invention there is provided a method carried out in a system that includes a non-volatile memory device. The method includes sequentially reading N bits of intermediate read data from a non-volatile memory cell of the non-volatile memory device, where N is an integer greater than one. The method also includes providing the N bits of the intermediate read data to N inputs of a logic circuit. The method also includes outputting N−1 bits of final read data from N−1 outputs of the logic circuit.

In accordance with another aspect of the invention there is provided a system that includes a memory device. The memory device includes a plurality of non-volatile memory cells. The memory device is configured to sequentially read N bits of intermediate read data from at least one of the non-volatile memory cells, where N is an integer greater than one. The system also includes an external controller that includes a logic circuit. The external controller is configured to receive the N bits of intermediate read data from the memory device and provide the N bits of the intermediate read data to N inputs of the logic circuit. The external controller is also configured to output N−1 bits of final read data from N−1 outputs of the logic circuit.

In accordance with another aspect of the invention there is provided a memory device. The memory device includes a memory array that includes a plurality of non-volatile memory cells. The memory device also includes a logic circuit that is communicatively coupled to the memory array. The memory device is configured to sequentially read N bits of intermediate read data from at least one of the non-volatile memory cells, where N is an integer greater than one. The memory device is also configured to input the N bits of the intermediate read data to N inputs of the logic circuit and output N−1 bits of final read data from N−1 outputs of the logic circuit.

In accordance with another aspect of the invention there is provided a method for storing input data in a non-volatile memory cell having multiple memory states providing a cell capacity for storing more than one bit of data, the multiple memory states being defined by respective threshold voltage ranges including an erase voltage range and a plurality of program voltage ranges. The method involves receiving input data having at least one bit less than the cell capacity, programming the memory cell in accordance with the input data using at least one bit less than the cell capacity such that at least one additional bit is not used for storing the input data. The method also involves performing a logical function on the input data to generate recovery data, the recovery data being operable to associate two adjacently located program voltage ranges with a single memory state, and programming the recovery data into the at least one additional bit.

In accordance with another aspect of the invention there is provided a memory apparatus. The apparatus includes a plurality of non-volatile memory cells each having multiple memory states providing a cell capacity for storing more than one bit of data, the multiple memory states being defined by respective threshold voltage ranges including an erase voltage range and a plurality of program voltage ranges. The memory is configured to store input data having at least one bit less than the cell capacity by programming the memory cell in accordance with the input data using at least one bit less than the cell capacity such that at least one additional bit is not used for storing the input data. The memory also includes a logic circuit configured to perform a logical function on the input data to generate recovery data, the recovery data being operable to associate two adjacently located program voltage ranges with a single memory state, the recovery data being programmed into the at least one additional bit.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Reference will now be made, by way of example, to the accompanying drawings:

FIG. 1 is a schematic view of a non-volatile memory cell;

FIG. 2 is a schematic diagram of a memory block incorporating the memory cell

FIG. 3 is a block diagram of a memory device incorporating the memory block shown in FIG. 2;

FIG. 4 is a block diagram of a system including the memory device of FIG. 3;

FIG. 5 is a graphical depiction of a distribution of the number of memory cells as a function of threshold voltage;

FIG. 6 is another graphical depiction of a distribution of the number of memory cells as a function of threshold voltage;

FIG. 7 is a process flowchart for programming and reading a memory cell in accordance with an example;

FIG. 8 is a graphical depiction of a distribution of the number of memory cells as a function of threshold voltage for the process example shown in FIG. 7;

FIG. 9 is a process flowchart for programming a memory cell in accordance with an embodiment of the invention;

FIG. 10 is a graphical depiction of a distribution of the number of memory cells as a function of threshold voltage for the process embodiment shown in FIG. 9;

FIG. 11 is a further graphical depiction of a distribution of the number of memory cells as a function of threshold voltage for the process embodiment shown in FIG. 9;

FIG. 12 is a process flowchart for reading data stored in a memory cell in accordance with the process of FIG. 9;

FIG. 13 is a graphical depiction of voltage ranges for implementing an alternative embodiment in accordance with the process of FIG. 9;

FIG. 14 is a further graphical depiction of voltage ranges for implementing the alternative embodiment in accordance with the process of FIG. 9;

FIG. 15 is a process for reading data stored in a memory cell in accordance with the alternative embodiment of FIGS. 13 and 14;

FIG. 16 is a graphical depiction of voltage ranges for storing three bits of data in a single memory cell;

FIG. 17 is a truth table for reading two bits of data stored in accordance with the embodiment of the FIG. 16;

FIG. 18 is a schematic diagram of a combinational logic circuit embodiment for implementing the truth table of FIG. 17;

FIG. 19 is a truth table for storing data in a memory cell in accordance with the embodiment of the invention of FIG. 17;

FIG. 20 is a schematic diagram of a combinational logic circuit embodiment for implementing the truth table of FIG. 19;

FIG. 21 is flowchart of a programming process for storing data in a memory cell in accordance with the embodiment shown in FIGS. 16-20

FIG. 22 is a flowchart of a process for reading data from a memory cell in accordance with the embodiment shown in FIGS. 16-20;

FIG. 23 is a process for reading data from a memory cell in accordance with a further embodiment of the invention; and

FIG. 24 is a graphical depiction of voltage ranges for storing the two bits of data in accordance with the process of FIG. 23.

### DETAILED DESCRIPTION

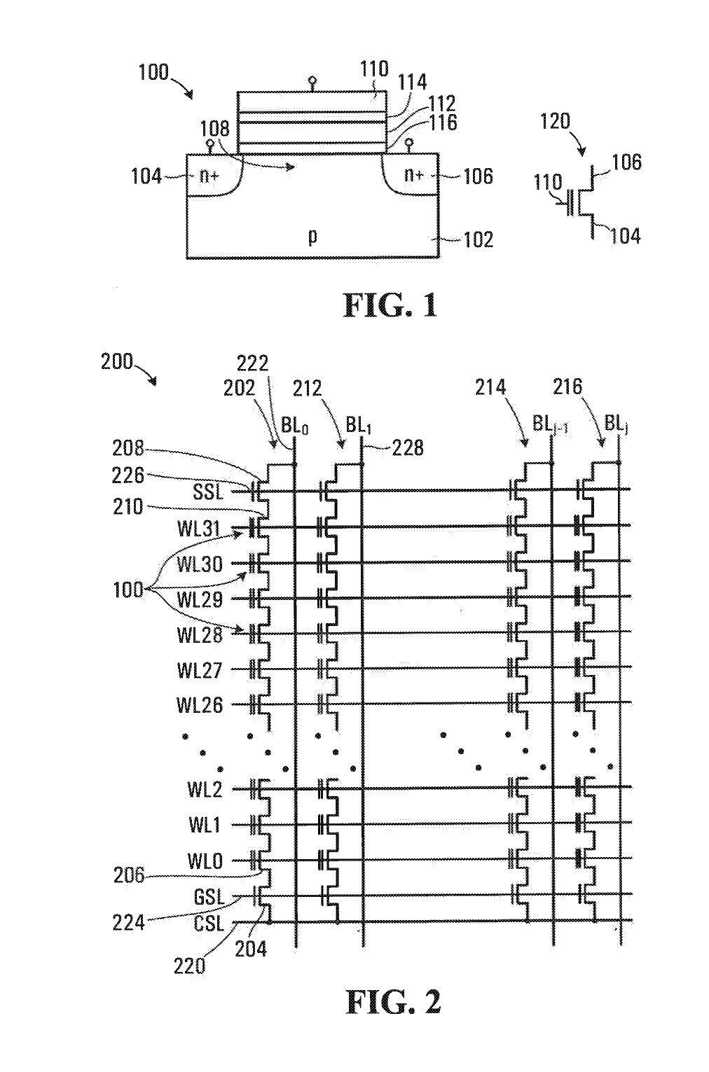

Referring to FIG. 1, an example of a non-volatile memory cell is shown generally at 100. The memory cell 100 includes a p-type substrate 102 having a source 104, a drain 106, and a channel 108 extending through the substrate between the source and the drain. The memory cell 100 also includes a control gate 110 and a floating gate 112. The floating gate 112 is disposed between the control gate 110 and the substrate 102 and is isolated by layers of oxide 114 and 116.

To configure the memory cell 100, a relatively high voltage is applied to the control gate 110 while keeping the source 104 and the drain 106 at ground potential. This operation, referred to as “programming” causes charge carriers in the channel 108 to tunnel through the oxide layer 116 and become trapped on the floating gate 112, thereby establishing a charge that is maintained for a long time due to the isolating oxide layers 114 and 116.

Reading the memory cell 100 involves applying a lower read voltage to the control gate 110. The charge on the floating gate 112 partially cancels the electric field caused by the read voltage V_{rd}, and the charge state of the floating gate 112 may be determined by testing the conductivity of the channel 108 by detecting whether a current flows through the channel under conditions established by the read voltage. The charge on the floating gate 112 is generally associated with a cell threshold voltage Vₜ and if Vₜ is less than V_{rd} the channel 108 should conduct current. If however, the cell threshold voltage Vₜ is greater than V_{rd}, then the channel 108 will not conduct current. Channel conduction may be detected by a sense amplifier (not shown), which may also include logic circuitry for latching the data read from the memory cell 100.

For storing a single binary digit (bit) in the memory cell 100 the floating gate 112 is charged to effect a threshold voltage difference (threshold voltage Vₜ) which depends on the capacitance from the control gate 110 to the floating gate 112 and from the floating gate 112 to the channel 108. When the floating gate 112 is not charged, the threshold voltage Vₜ will generally be negative corresponding to an erase voltage range, which is a first of two defined threshold voltages ranges and is generally assigned to data “1”. The memory cell 100 may be configured for a threshold voltage Vₜ falling within a program voltage range, which is the second of the two defined threshold voltages ranges, by performing a programming operation on the memory cell. The programming operation generally involves applying a program voltage V_{pgm} to the control gate 110, with the substrate 102, source 104, and drain 106 held at ground potential while periodically detecting the accumulated charge on the floating gate 112 by testing the conductivity of the channel 108 as described above. Programming thus involves successive charge cycles each followed by a sensing cycle. Programming is discontinued when the accumulated charge on the floating gate 112 falls within the defined program voltage range assigned to a desired data state, for example data “0”.

In general, configuring the memory cell 100 in the erase state occurs in an erase operation that acts on a plurality of memory cells, resetting each of the cells to data “1”. Accordingly, when input data “1” is received for storing in the memory cell 100, the threshold voltage Vₜ should be within the erase voltage range and, while when input data “0” is received, the cell is programmed to move the threshold voltage Vₜ into the program voltage range. When it is desired to store input data “1” in a memory cell 100 that is already programmed (i.e. data “0”), the cell must first be erased along with a plurality of other memory cells in an erase operation.

A schematic symbol representing the memory cell is shown at 120 in FIG. 1. Alternative configurations of memory cell having silicon nitride or silicon nanocrystal charge traps may also be implemented in place of the floating gate memory cell 100 shown in FIG. 1.

In one example memory cells may be connected in a string to form a memory block, a portion of which is shown in FIG. 2 at 200. The memory block 200 includes a plurality of memory cells 100 (in this example 32 memory cells) connected source to drain in series in a NAND string 202. The memory block 200 includes a ground select transistor 204, which has a source connected to a common source line 220 (CSL) and a drain connected to a source of a first memory cell 206 in the NAND string 202. The memory block 200 also includes a string select transistor 208, which has a drain connected to a bitline 222 (BL₀) and a source connected to a drain of a first memory cell 210 in the NAND string 202. Each memory cell in the NAND string 202 has a wordline (WL) connected to the control gate of the cell. The control gate of the ground select transistor 204 is connected to a ground select line 224 (GSL) and the control gate of the string select transistor 208 is connected to a string select line 226 (SSL).

In example shown the memory block 200 includes a second NAND string 212, having a bitline 228 (BL₁) and sharing the respective wordlines WL0-WL31 with the NAND string 202. The ground select line 224 and string select line 226 are also shared with the NAND string 202. The memory block 200 will generally include a plurality of NAND strings for implementing a desired byte length. In FIG. 2, further NAND strings 214 and 216 are shown connected to respective bitlines BLⱼ₋₁ and BLⱼ. Additional NAND strings may also be included for error management functions, such as storing error-correcting codes (ECC) used by an ECC engine for correcting errors in read data, for example. A byte or word of data may be written or read from a page of memory by applying a string select signal to the string select line 226, and by applying appropriate voltages to the ground select line 224, wordline, and bitlines BL₀-BLⱼ, as described above in connection with the memory cell 100 shown in FIG. 1.

Memory cells 100 in the memory block 200 connected to a common wordline are generally referred to as a “page” of memory and the memory block 200 would thus comprise 32 pages of memory. In the example shown the memory block 200 is j bytes wide by 32 pages. Programming and reading data to and from the memory block 200 occurs on a page-wide basis, while erasing of memory cells generally occurs on a block-wide basis i.e. all cells in a block are erased together in a block wide erase operation. Partial block erase is also possible as disclosed in U.S. Pat. No. 7,804,718 of Kim entitled “Partial Block Erase Architecture for Flash Memory”.

In other examples the memory cell 100 may be incorporated in a memory configuration other than a NAND string configuration such as shown in FIG. 2. For example, a plurality of memory cells generally as shown at 100 in FIG. 1 may also be configured to provide a NOR flash memory or other configuration of memory.

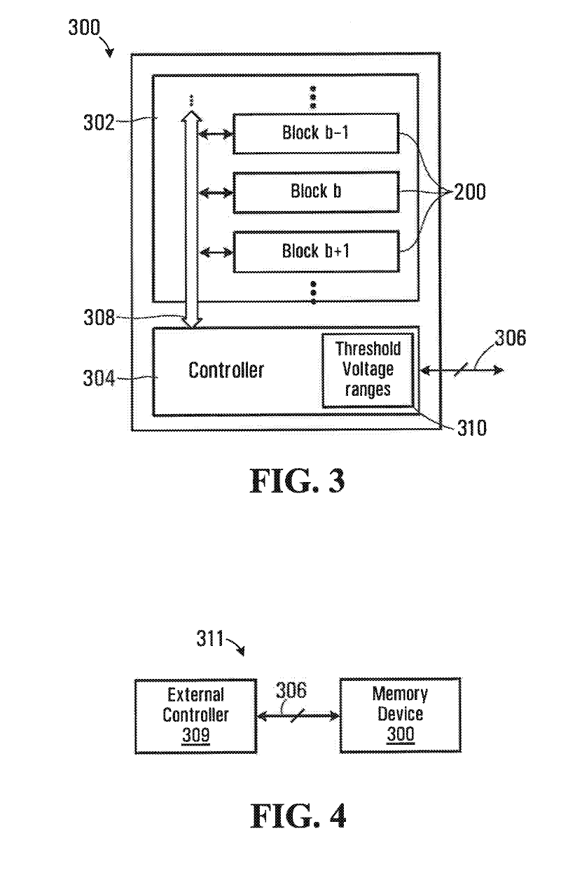

Referring to FIG. 3, a memory device is shown schematically at 300. The memory device 300 includes a plurality of memory blocks 200 arranged in a memory array 302. The memory device 300 also includes a controller 304 having an input/output interface 306 providing interface functions between the memory and an external controller 309 of system 311 shown in FIG. 4. The external controller may be any suitable device for controlling the operation of the memory device 300 such as, for example, a memory controller or a processor.

Referring again to FIG. 3, the memory device 300 also includes an interconnect 308 between the controller 304 and the memory array 302. The interconnect 308 may include a plurality of conventional memory elements for interconnecting between memory blocks 200 in the array 302 and the controller 304 such as row-decoders, wordlines, bitlines, column-decoders, page buffers, and sense amplifiers. The controller 304 controls functions of the memory device 300 such as executing commands received on the input/output 306, programming data received at the input/output to the memory array 302, reading data from the memory array 302, providing data to the input/output 306, and erasing data from the memory blocks 200.

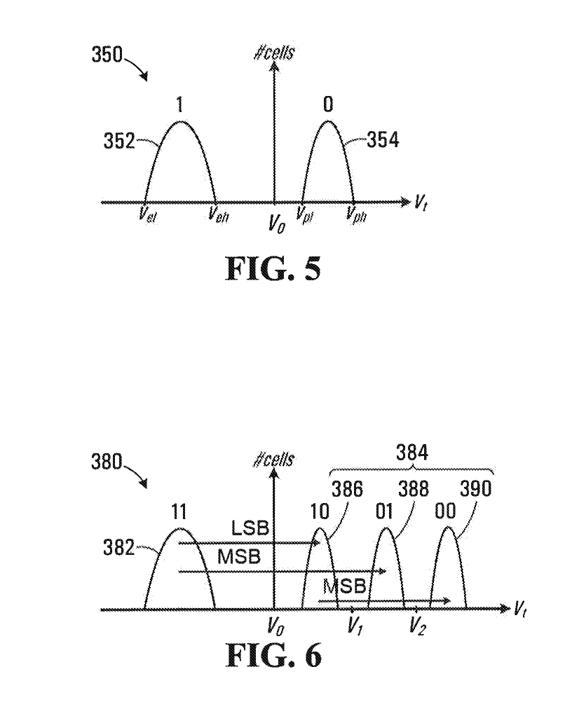

When a memory cell is programmed, the threshold voltage Vₜ may take up any of a range of values within the program voltage range. Accordingly, there will be a variation in threshold voltage Vₜ between different memory cells 100 programmed in the same voltage range within the memory block 200 and the memory device 300. Referring to FIG. 5, a distribution of the number of memory cells 100 as a function of threshold voltage Vₜ for a memory such as the memory device 300 is shown graphically at 350. In each memory block 200, some of the memory cells 100 will be in the erase state with the respective threshold voltages Vₜ being distributed over an erase voltage range 352 due to small differences in residual charge on the floating gate 112.

In this case the erase voltage range 352 includes threshold voltages Vₜ between a low voltage limit for the range (Vₑₗ) and a high voltage limit for the range (Vₑₕ). Statistically, a greater number of memory cells 100 in the erase state will have threshold voltages Vₜ toward the center of the erase voltage range 352, thus forming the distribution shown in FIG. 5. In this case the erase voltage range 352 includes negative voltages extending between Vₑₗ and Vₑₜ, and cells having a threshold voltage in this range are taken to represent data “1”.

During programming the threshold voltage Vₜ of a memory cell is increased from within the erase voltage range 352 by causing negative charge to accumulate on the floating gate 112 until the threshold voltage is within a program voltage range 354. The program voltage range 354 includes threshold voltages Vₜ between a low voltage limit for the range (Vₚₗ) and a high voltage limit for the range (Vₚₕ). In this case, the program voltage range includes positive voltages extending between Vₚₗ and Vₚₕ and threshold voltages Vₜ in this range are taken to represent data “0”.

Reading the memory state of a memory cell generally involves applying a read voltage V_{rd} intermediate between Vₑₕ and Vₚₗ and testing for channel conduction. For the case shown in FIG. 5, this may involve applying a read voltage V_{rd} of 0 volts to the bitlines and a voltage of 0 volts to the word line of the page being read. A voltage is also applied to all of the wordlines of other memory cells 100 in the NAND strings (202, 212, 214, 216 in FIG. 2) to cause the channels of these memory cells to conduct. If under these conditions the NAND string conducts, then the memory cell being read has a threshold voltage Vₜ within the erase voltage range 352, and the cell is thus in the erased state and data “1” is read. If the NAND string does not conduct, then the cell being read has a threshold voltage Vₜ within the program voltage range 354 and the cell is thus in the program state (i.e. data “0” is read). For a memory cell configured for only two memory states, the separation between the voltage ranges 352 and 354 is relatively large and provides a correspondingly wide read margin for reliable reading of memory cells, even if the threshold voltage of a particular cell were to drift outside of the voltage ranges 352 and 354.

The upper and lower limits for the voltage ranges 352 and 354 are generally selected as a tradeoff between a time taken to program and erase a memory cell and the margins for data storage in the cell. While a greater separation between the voltage ranges 352 and 354 potentially provides improved margins for more reliable storage, the time taken to program or erase the memory cells increases since the greater accumulation of charge on the floating gate 112 is required for greater separation. Referring back to FIG. 3, the controller 304 of the memory device 300 includes a set of threshold voltage ranges 310 for configuring the voltage ranges 352 and 354. The set of threshold voltage ranges 310 may include values for Vₑₗ, Vₑₕ, Vₚₗ, and Vₚₕ stored in a memory area of the controller provided for storing operating algorithms and/or configuration parameters. Alternatively, the voltage ranges 310 may be hard-coded in the controller 304 during manufacture by metal masking or wire-bonding, for example. The voltage ranges 352 and 354 for programming the memory cells 100 may thus be shifted along the Vₜ axis and/or broadened or narrowed, either in a configuration step at the time of fabrication, or by storing configurations in the code storage of the controller 304.

Configuration of the voltage ranges 352 and 354 as shown in FIG. 5 facilitates storing of a single bit in each memory cell. The memory device 300 may be alternatively configured to implement a plurality of memory states in each memory cell, thus facilitating storing of multiple bits of data in each cell. The plurality of memory states are provided by programming the floating gate 112 of the memory cells to a threshold voltage Vₜ within one of a plurality of program voltage ranges. The plurality of program voltage ranges may defined by the set of threshold voltage ranges 310 stored in the controller 304.

Referring to FIG. 6, a distribution of the number of memory cells as a function of threshold voltage Vₜ for storing two bits of data in each memory cell is shown graphically at 380. The threshold voltages Vₜ for each cell fall within one of an erase voltage range 382 and a plurality of program voltage ranges 384. The plurality of program voltage ranges 384 include a first program voltage range 386 adjacent to the erase voltage range 382 and two higher program voltage ranges 388 and 390. The voltage ranges 382, 386, 388, and 390 represent four possible memory states in which the cell may be programmed to store two bits of data. Several different encoding schemes may be used to assign the four memory states to the four possible data bit combinations “11”, “10”, “01” and “00”. One possible encoding scheme is shown in FIG. 6 where the erase voltage range is associated with data “11”, the first program voltage range 386 is associated with data “10” and the higher program voltage ranges 388 and 390 with data “01” and “00” respectively. Alternative encoding schemes may assign the plurality of program voltage ranges 384 differently, while still assigning the erase voltage range 382 to data “11”. Each memory cell may thus be used to store a lower page bit of data and an upper page bit of data.

In a memory apparatus such as the memory device 300, the memory cells 100 would generally have an initial voltage threshold Vₜ in the erase voltage range 382. Also, those skilled in the art will appreciate that for a non-volatile memory cell (such as, for example a NAND-type memory cell or a NOR-type memory cell) the initial voltage threshold Vₜ can be adjusted by ion implantation. Both NAND and NOR memory cells have a floating gate which stores electrons. The cell state of empty (i.e. no electrons) the floating gate is typically set as the erase state. Similarly, a cell state corresponding to electrons in the floating gate is a program state. Because of cell structure in NAND and NOR memories, the Vₜ of an erased cell is negative in a NAND memory cell and positive in a NOR memory cell. Again, erased cell Vₜ can be adjusted to either negative or positive by ion implantation.

With reference still to FIG. 6, programming the least significant bit of data involves charging the floating gate 112 to configure the threshold voltage of the cell in the first program voltage range 386, such that the least significant bit changes from a “1” to a “0”. For programming the higher order bit, if the memory cell is configured in the erase voltage range 382, the floating gate 112 is charged to configure the cell threshold voltage Vₜ within the program voltage range 388. If the cell is already configured in the first program voltage range 386, the floating gate 112 is charged to configure the cell voltage in the higher program voltage range 390.

Data stored in a memory cell in accordance with the encoding scheme shown in FIG. 6 may be read by applying a series of read voltages V_{rd} to the bitline for the memory cell as described earlier herein. For the encoding scheme shown in FIG. 6, reading the higher order bit requires application of only a single read voltage V₁, which if the channel conducts indicates that the memory cell is configured either within the first program voltage range 386 or the erase voltage range 382. In this case the higher order bit is read as data “1”.

Reading the least significant bit requires application of read voltages V₀, V₁, and V₂. If channel conduction occurs at voltage V₁ then the memory cell is configured for a threshold voltage Vₜ within either the first program voltage range 386 or the erase voltage range 382, and a further read at voltage V₀ is required to determine the least significant bit. If the channel conducts at read voltage V₀ then the memory cell is configured in the erase voltage range 382 and the least significant data bit is “1”. If channel conduction does not occur at voltage V₁ then the memory cell is configured for a threshold voltage Vₜ within either of the two higher program voltage ranges 388 or 390, and a further read at voltage V₂ is required to determine the least significant bit. If the channel conducts at V₂ then the memory cell is configured in the program voltage range 388 and the least significant data bit is read as data “1”. Reading the least significant bit thus requires testing channel conduction at each of the voltages V₀, V₁, and V₂.

The voltage range configuration shown in FIG. 6 for storing multiple bits of data may be implemented for only specific memory blocks 200 in the memory device 300 (shown in FIG. 3), or for all memory blocks in the memory. The physical configuration of the memory cells 100 and memory blocks 200 may be substantially similar regardless of whether a single bit or multiple bits of data are stored. The configuration may be implemented by changes in the controller 304, for example by changing the set of threshold voltage ranges 310, and by changing algorithms associated with read operation implementation.

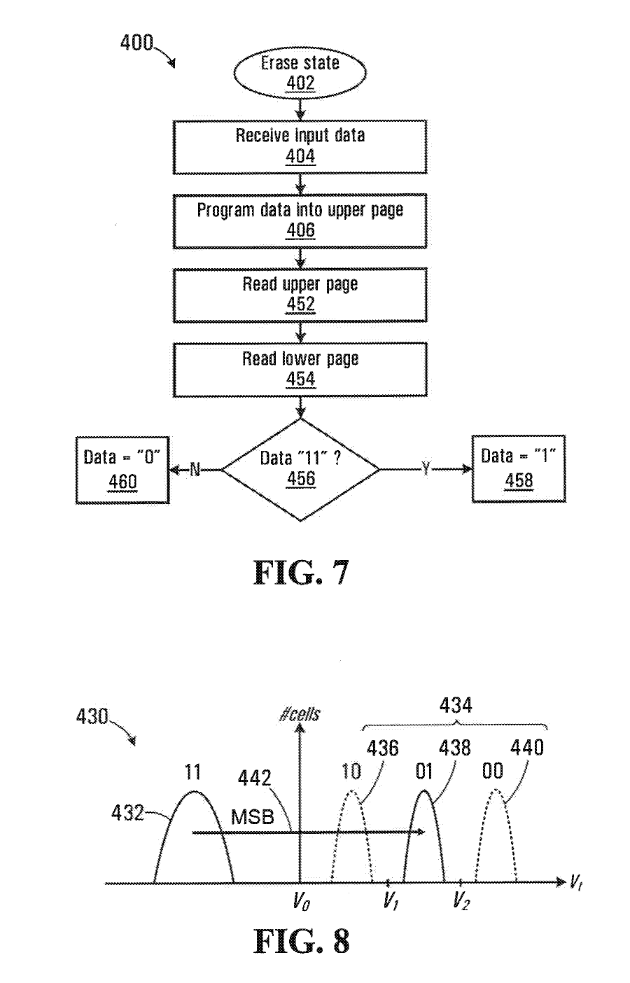

A process flowchart for programming and reading a memory cell in accordance with an example is shown generally at 400 in FIG. 7. Voltage ranges for programming the memory cell in accordance with this example are shown generally at 430 in FIG. 8 and include an erase voltage range 432, and a plurality of program voltage ranges 434. The plurality of program voltage ranges 434 includes a first program voltage range 436 adjacent to the erase voltage range and a plurality of higher program voltage ranges 438 and 440. The voltage ranges defined in FIG. 8 generally correspond to the voltage ranges shown in FIG. 6 and the memory cell is thus has a configured capacity for storing two bits of data. The encoding scheme for assigning the four memory states possible data bit combinations also generally corresponds to the encoding scheme shown in FIG. 6. The first program voltage range 436 is associated with programming a least significant bit in the memory cell and the plurality of higher program voltage ranges 438 and 440 are associated with programming a higher order bit in the memory cell.

The processes 400 begins at block 402, where the memory cell is in the erase state. The processes 400 continues at block 404, when the memory cell receives input data for programming in the cell. In this illustrative example where the capacity of the memory cell is two bits of data, the input data thus comprises a single bit of data. The processes 400 then continues at block 406 where the single bit of input data is programmed into the upper page. Accordingly, if the input data is “1” then the threshold voltage Vₜ of the memory cell remains in the erase voltage range 432. However if the input data is “0”, then the threshold voltage Vₜ of the memory cell is moved into the program voltage range 438 as indicated by the arrow 442 in FIG. 8. The first program voltage range 436 thus remains unused and the input data stored in the memory cell is indicated by configuration of the memory cell in either the erase voltage range 432 or the program voltage range 438. In this example, the program voltage range 440 also remains unused.

The single bit of input data is stored in the memory cell in the program voltage range 438. This provides greater separation between voltage ranges 432 and 438 that are used to store the single bit of input data. Furthermore, since the program voltage range 440 is also not used, programming time for the memory cell is also reduced, since the charge on the floating gate 112 need only be moved up to the intermediate program voltage range 438 and not to the higher program voltage range 440. Programming the higher program voltage range 440 is associated with greater stresses on the memory cell due to charging of the floating gate 112, and avoiding use of this voltage range potentially increases the number of programming cycles that the memory cell can withstand before unreliable storage becomes an issue.

Referring again to FIG. 7, a reading process of the processes 400 is now described. The reading process generally involves applying a series of read voltages V_{rd} to a corresponding bitline for the memory cell. At block 452, the upper page is read by applying a single read voltage V₁, which if the channel conducts indicates that the memory cell has a threshold voltage Vₜ configured within either the erase voltage range 438 or the first program voltage range 436. Since the first program voltage range 436 is not used, a single read at voltage V₁ (or at an alternative voltage somewhere between V₀ and V₁ if the MLC flash memory device were to be so customized) should be technically sufficient to distinguish between a configured threshold voltage Vₜ in the erase voltage range 432 and the program voltage range 438. However, in some examples, such as when the processes 400 are implemented in a standard MLC flash memory device without certain read customizations in relation to internal device operation, the reading process continues at block 454, where the lower page is also read by applying read voltages V₀, V₁, and V₂ as described above in connection with FIG. 6 for reading the least significant bit of data stored in the cell.

The reading process then continues at block 456, where a determination is made as to whether the intermediate read data from the memory cell is data “11”, in which case at block 458 the cell is determined to be unambiguously configured in the erase voltage range 432 and the output data (final read data) is thus data “1”. However, if at block 456 the intermediate read data from the memory cell is either data “10”, “01”, or “00” (i.e. not data “11”) then at block 460 the single bit of output data (final read data) for the cell is determined to be “0”.

In general, the erase voltage range 432 is wider than the plurality of program voltage ranges 434. Furthermore, since the erase state corresponds to a lack of charge on the floating gate 112 of the memory cell, charge leakage is less of an issue and threshold voltages Vₜ in the erase voltage range 432 are unlikely to drift, thus providing an improved read margin for cells in the erase state. This being said, those skilled in the art will appreciate that an erased cell could gain electrons by program disturbance in neighboring cells; however there is, in any event, a correspondingly lower probability of a cell voltage Vₜ within the erase voltage range 432 drifting or being disturbed. While the programming time for storing a single bit in the memory cell in accordance with the processes 400 is less than for the two bit storage case of FIG. 6, the read time remains the same.

Additional variations in the processes 400 are contemplated. For example, the order of the illustrated blocks need not necessarily be exactly as illustrated (more generally, for any flow chart later discussed the same statement regarding ordering of illustrated blocks applies). It is, for instance, contemplated that the reading of the lower page (block 454) may occur before the reading of the upper page (block 452).

As another example of additional variations, even in a MLC flash memory device with read customizations as previously described, there may be conditions where the device still reads the lower page such as, for example, in the event that the threshold voltage Vₜ of the cell drifts below V₁. In such instances, the block 454 thus facilitates a determination as to whether the initially programmed threshold voltage Vₜ of the cell has drifted below V₁ or drifted above V₂. A drift in the threshold voltage Vₜ of a cell may occur due to charge leakage on the floating gate 112 of the memory cell over time. Additionally, when a memory cell of the memory block 200 (shown in FIG. 2) is read, unselected cells in the NAND string 202 are configured to conduct, which may cause a small change in the stored charge on the floating gate 112 of these cells. This effect, known as a read disturbance, may also cause changes in the threshold voltage Vₜ of a memory cell due to capacitive coupling from adjacent cells being programmed.

As noted above, a NAND memory block such as shown in FIG. 2 may be arranged in pages, each page being addressable through a respective wordline. When storing multiple bits per memory cell, it is common to use the terminology “lower page” and “upper page”. Each of the pages may be viewed as separate memory locations for storing data, even though these pages are stored in the same physical cell. The controller 304 of the memory device 300 may be configured to provide access to the upper and lower pages for programming and reading operations, which permits a user to access these pages generally as if they were physical pages of memory.

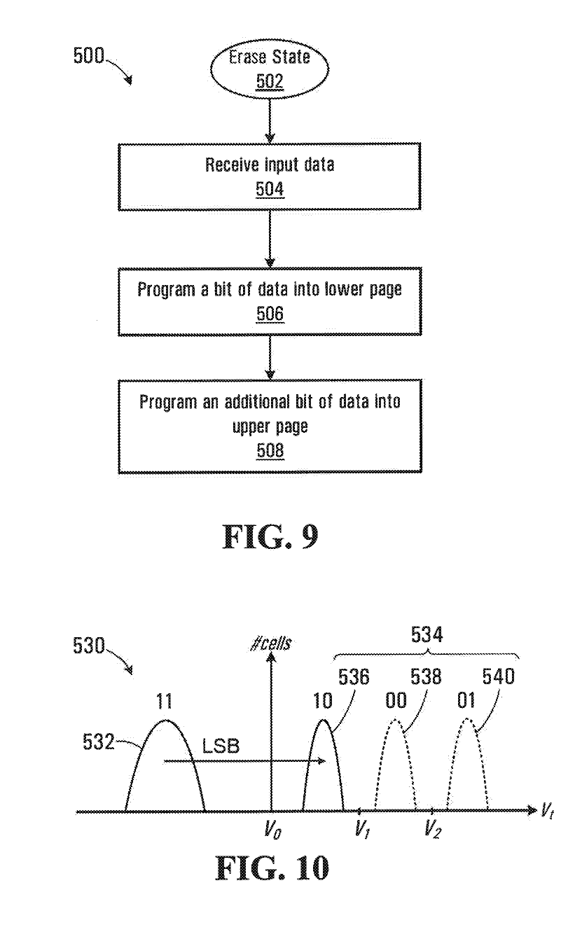

Referring to FIG. 9, a process flowchart for programming a memory cell in accordance with an embodiment of the invention is shown generally at 500. Voltage ranges for programming the memory cell in accordance with this embodiment of the invention are shown generally at 530 in FIG. 10, and include an erase voltage range 532, and a plurality of program voltage ranges 534. The program voltage ranges 534 include a first program voltage range 536 adjacent to the erase voltage range 532 and a plurality of higher program voltage ranges 538 and 540. The memory cell in this embodiment also has a configured capacity for storing two bits of data. The encoding of the voltage ranges 538 and 540 is reversed from the example shown in FIG. 8. The higher program voltage ranges 538 and 540 are however still associated with upper page programming in the memory cell.

The process 500 begins at block 502, where the memory cell is in the erase state. The process continues at block 504, with the memory cell receiving input data, which in the present example is a single bit for a cell having a two bit capacity. The process then continues at block 506 where first stage programming occurs. More specifically, the single bit of input data is programmed into the lower page. Referring to FIG. 10, if the input data is “1”, then the threshold voltage Vₜ of the memory cell remains within the erase voltage range 532, while if the input data is “0”, the threshold voltage Vₜ is moved into the first program voltage range 536.

Referring again to FIG. 9, the process then continues at block 508 where second stage programming occurs. More specifically, an additional bit of data is then programmed into the upper page. This additional bit of data is a logical function of the single bit of input data. In particular, the logical function is, for this example, additional bit of data equals the single bit of data.

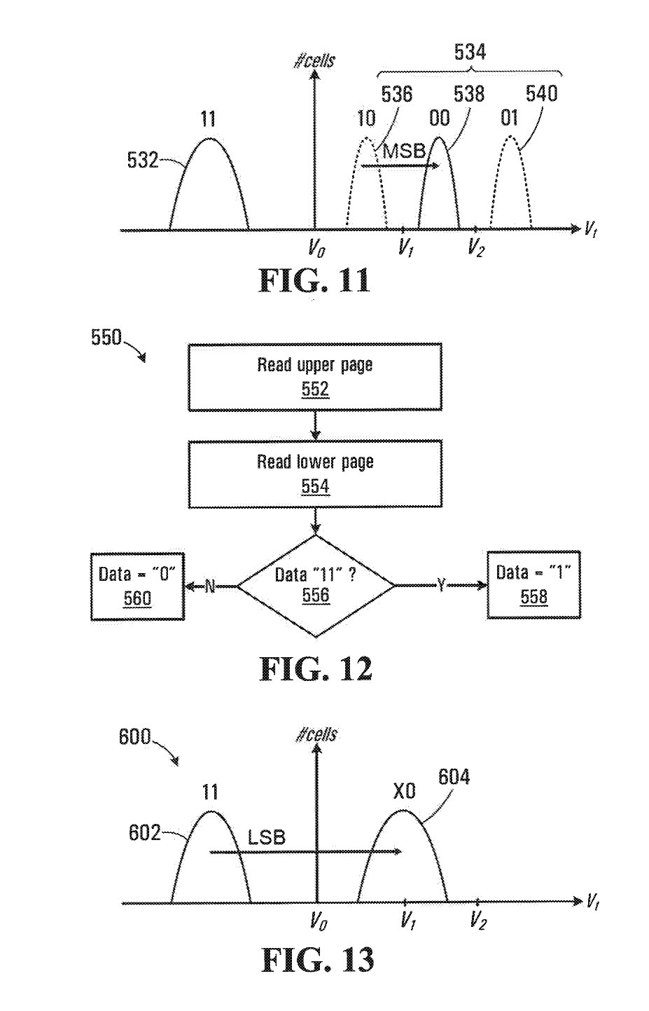

Referring to FIG. 11, if the input data is “1”, the threshold voltage Vₜ of the memory cell remains within the erase voltage range 532. However, if the input data is “0”, then following the block 506 the threshold voltage Vₜ would be within the first program voltage range 536. In this case the threshold voltage Vₜ is then moved up into the program voltage range 538. The lower and upper page are thus both programmed in accordance with the same single bit of input data and the voltage ranges 532 and 538 are used to store the single bit of input data. The voltage ranges 536 and 540 remain unused.

In this embodiment, two sequential programming steps represented by FIG. 10 and FIG. 11 are required, and programming will thus be correspondingly slower than for the first example shown in FIGS. 6-7. However, since the highest program voltage range 540 remains unused, there is still a reduction in programming time over the multiple-bit storage example shown in FIG. 6.

Referring to FIG. 12, a process for reading data stored in a memory cell programmed in accordance with the process 500 is shown generally at 550. At block 552, the upper page is read by applying a single read voltage V₁, which if the channel conducts indicates that the memory cell has a threshold voltage Vₜ configured within either the erase voltage range 538 or the first program voltage range 536. The process 550 continues at block 554, where the lower page is also read by applying read voltages V₀ and V₂. For the encoding scheme shown in FIGS. 10 and 11, it is not necessary to read at voltage V₁, since both the first program voltage range 536 and higher program voltage range 538 have an assigned least significant bit of “0”; however if the process 550 is implemented in a standard MLC flash memory device without certain read customizations in relation to internal device operation, then it is expected that such an MLC flash memory device would automatically read at all the voltages V₀, V₁ and V₂ to get the lower page data. Excluding the above mentioned considerations of standard MLC flash memory devices, the read voltage at V₂ should be sufficient to unambiguously determine whether the data stored in the cell has a least significant bit of “0” (program voltage ranges 536 or 538) or “1” (program voltage range 540), and thus a read at voltage V₁ is not necessary in all instances.

The process 550 then continues at block 556, where a determination is made as to whether the intermediate read data from the memory cell is data “11”, in which case at block 558 the cell is unambiguously determined to be configured in the erase voltage range 532 and the final read data is thus data “1”. However, if at block 556 the intermediate read data from the memory cell is either data “10”, “00”, or “01(i.e. not data “11”) then at block 560 the single bit of output data (final read data) for the cell is determined to be “0”.

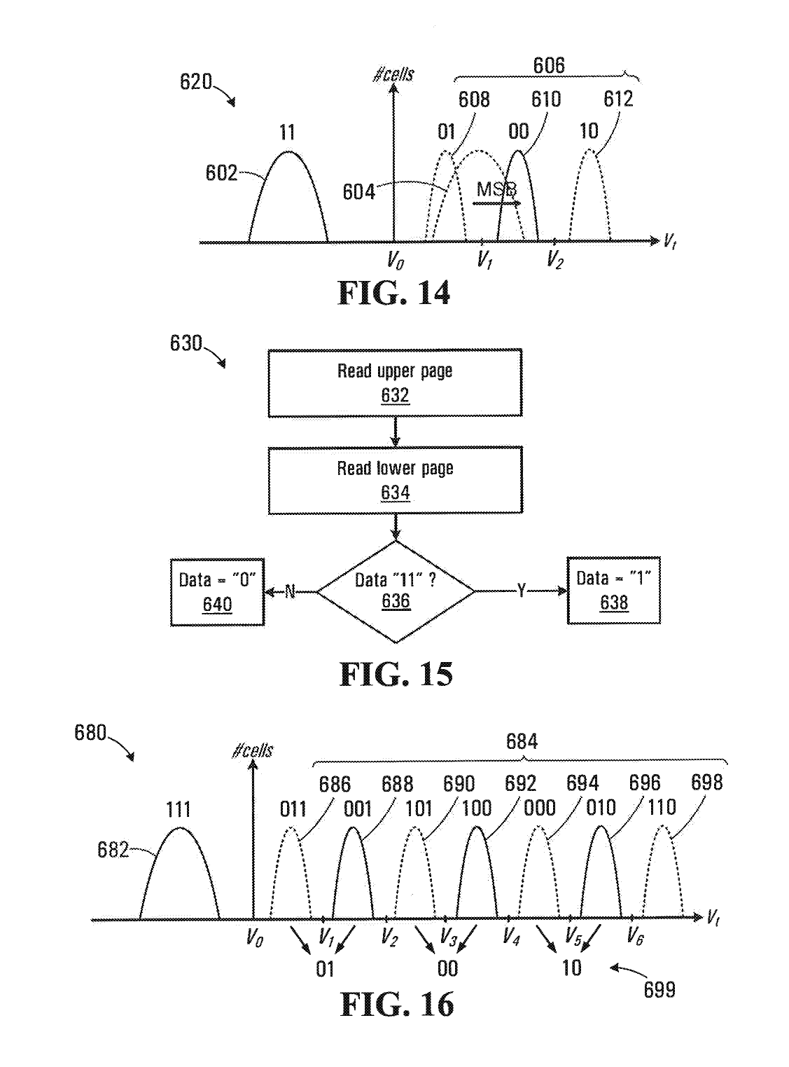

The same process 500 as shown in FIG. 9 may be also used for programming a memory cell in accordance with another embodiment of the invention. Voltage ranges for this embodiment are shown at 600 in FIGS. 13 and 620 in FIG. 14. Referring to FIG. 13, the erase voltage range 602 generally corresponds to the erase voltage range 532 in FIG. 9. However, in this embodiment a temporary program voltage range 604 is defined for the purposes of lower page programming. The temporary program voltage range 604 is wider than program voltage ranges described earlier herein, and may be programmed relatively quickly due to the larger range of permitted threshold voltages Vₜ. A set of voltage ranges for upper page programming of the memory cell in accordance with this embodiment of the invention are shown in FIG. 14 and include a plurality of program voltage ranges 606. The plurality of program voltage ranges 606 include a first program voltage range 608 adjacent to the erase voltage range 602 and a plurality of higher program voltage ranges 610 and 612.

Referring back to FIG. 9, at block 506 of the process 500, if the input data is “1” then the threshold voltage Vₜ of the memory cell remains within the erase voltage range 602 shown in FIG. 13. If the input data is “0” then the threshold voltage Vₜ is moved into the temporary program voltage range 604. The process 500 continues at block 508, where the single bit of input data is then programmed into the upper page. Referring again to FIG. 14, if the input data is “1” then the threshold voltage Vₜ of the memory cell remains within the erase voltage range 602. However, if the input data is “0”, then following block 506 the threshold voltage Vₜ would be within the temporary program voltage range 604, and the threshold voltage Vₜ is then moved up into the higher program voltage range 610. Just like before, the first program voltage range 608 and higher program voltage range 612 are not used. Both the lower and upper pages are programmed in accordance with the same single bit of input data and the voltage ranges 602 and 610 are used to store the single bit of input data.

Referring to FIG. 15, a process for reading data stored in a memory cell in accordance with this embodiment is shown generally at 630. At block 632, the upper page is read by application of a read voltage V₂, which if the channel conducts indicates that the memory cell has a threshold voltage Vₜ configured within one of the erase voltage range 602, the first program voltage range 608, or the program voltage range 610. Reading the upper page further involves applying read voltage V₀, which if the channel conducts indicates that the memory cell has a threshold voltage Vₜ configured within the erase voltage range 602. Accordingly, a threshold voltage Vₜ within either the erase voltage range 602 or program voltage range 612 corresponds to a higher order data bit “1”, while a threshold voltage Vₜ within either of the program voltage ranges 608 or 610 corresponds to a higher order data bit “0”.

The process 630 continues at block 634, where the lower page is read by applying a read voltage V₁, which is sufficient to unambiguously determine whether the data stored in the cell has a least significant bit of “0” (program voltage ranges 610 or 612) or “1” (program voltage range 608). As previously discussed though, reading at all voltages may be carried out in any event in the case of a standard MLC flash memory device.

The process then continues at block 636, where a determination is made as to whether the intermediate read data from the memory cell is data “11”, in which case at block 638 the cell is unambiguously determined to be configured in the erase voltage range 602 and the stored bit is thus data “1”. However, if at block 636 the intermediate read data from the memory cell is either data “01”, “00”, or “10” (i.e. not data “11”) then at block 640 the single bit of output data (final read data) for the cell is determined to be “0”.

The above embodiments have been described for a memory cell having capacity for storing two bits. In other embodiments program voltage ranges for a memory cell may be configured to permit storing more than two bits. Referring to FIG. 16, voltage ranges for storing three bits of data in a single memory cell are shown generally at 680. The voltage ranges include an erase voltage range 682 and a plurality of program voltage ranges 684. The plurality of program voltage ranges 684 include a first program voltage range 686, and higher program voltage ranges 688, 690, 692, 694, 696, and 698. When using the memory cell to store three bits of data, the program voltages 684 would be used. For storing only two bits in the memory cell, the program voltage ranges 688, 692, and 696 may be used, while program voltage ranges 686, 690, 694, and 698 may remain unused, thus providing greater margin for reliable data storage and reading.

In a memory cell, charge leakage on the floating gate 112 over time may cause a cell threshold voltage Vₜ to drift into an immediately adjacent lower voltage range, particularly at higher temperatures. In another embodiment of the invention, a memory cell having a configured capacity for storing three bits of data may be used for reliable storage of two bits of input data. Still referring to FIG. 16, in this embodiment both voltage ranges 686 and 688 are associated with two bit output data “01” (indicated at 699) and thus if the threshold voltage of a cell programmed in the program voltage range 688 were to drift below 16, the read output data would not change. Similarly, voltage ranges 690 and 692 are associated with two bit output data “00”, and voltage ranges 694 and 696 are associated with two bit output data “10”.

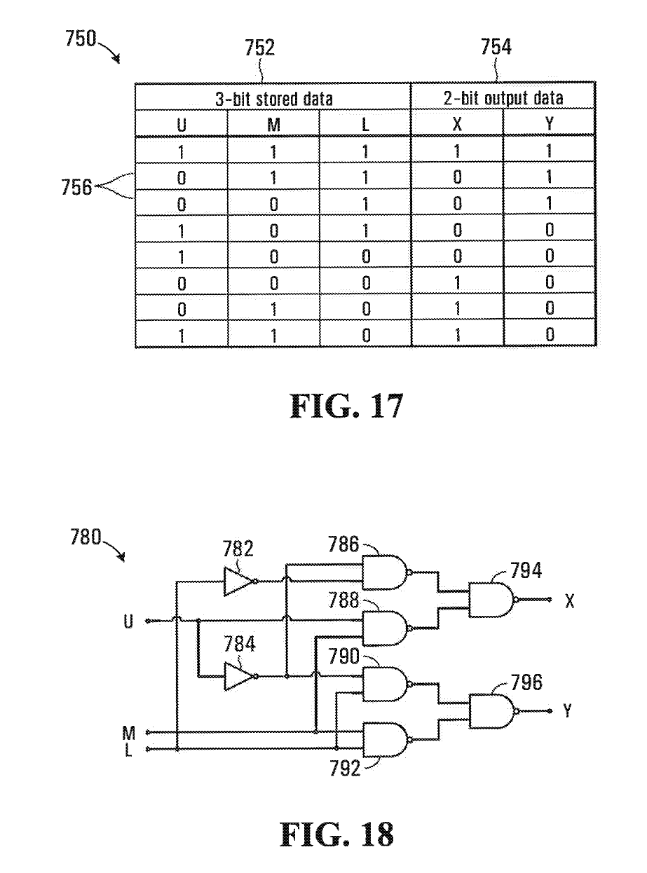

A truth table for reading output data in accordance with this embodiment of the invention is shown at 750 in FIG. 17. Referring to FIG. 17, the truth table 750 maps three bits of stored data 752 to two bits of output data 754. The stored data 752 includes a lower page bit (L), a middle page bit (M), and an upper page bit (U) and the output data 754 includes bits X and Y. When reading data stored in the memory cell, if the threshold voltage Vₜ of the memory cell is read within a lower unused program voltage range (shown in FIG. 16), then the two-bit output data for the cell is interpreted as corresponding to an adjacent higher program voltage range. The erase voltage range 682 representing stored data “111” thus maps to output data “11” in the first row of the table 750. Stored data associated with adjacent pairs of program voltage ranges are each mapped to a two-bit output data value in the truth table 750. Using a Karnaugh map to derive Boolean expressions for X and Y from the truth table 750, yields the following:

X=Ū. L̅+U.M Eqn. 1

Y=Ū.L+M.L Eqn. 2

where “Ū” represents logic NOT, “U.M” represents a logic AND function, and “+” represents a logic OR function. A combinational logic circuit for implementing the logic in Eqn's 1 and 2 to read two bits of data, X and Y stored in a memory cell using three bits of data U, M and L is shown in FIG. 18 at 780. The logic circuit 780 is implemented using NOT gates 782 and 784 and NAND gates 786-796. De Morgan's theorem was used to re-write the above Boolean expressions in Eqn's 1 and 2 as follows:

$$\begin{matrix}X = \overline{\overline{\overline{U} \cdot \overline{L}} \cdot \overline{U \cdot M}} & Eqn 3 \\ Y = \overline{\overline{U} \cdot L \cdot \overline{M \cdot L}} & Eqn 4\end{matrix}$$

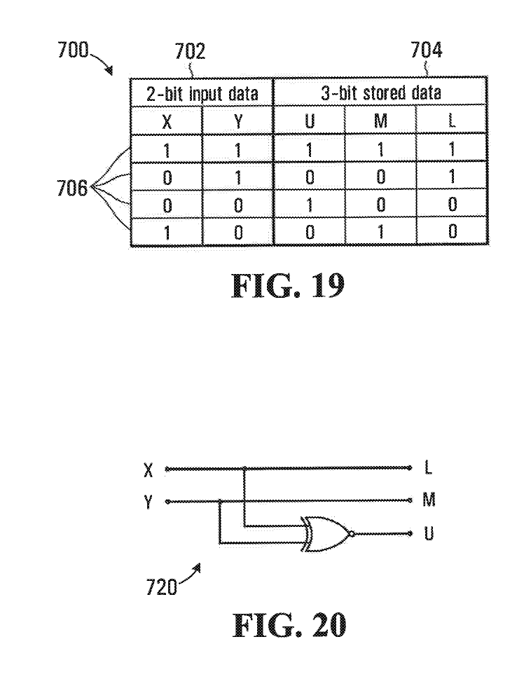

A truth table for storing data in a memory cell in accordance with this embodiment of the invention is shown at 700 in FIG. 19, and maps storage of two bits of input data 702 as three bits of stored data 704. In the truth table 700, the input data 702 in the cell includes bits X and Y, and the stored data includes a lower page bit (L), a middle page bit (M), and an upper page bit (U). The rows 706 in the truth table 700 map between two bit input data 702 and three bit stored data 704. Inspection of the truth table 700 yields the following Boolean expressions:

L=Y Eqn 5

M=X Eqn6

U=XNOR(X, Y) Eqn 7

where XNOR is an exclusive NOR logical function. A combinational logic circuit for implementing the logic in Eqn's 5-7 to program three bits of data, U, M and L representing the two bits of input data into a memory cell is shown in FIG. 20 at 720.

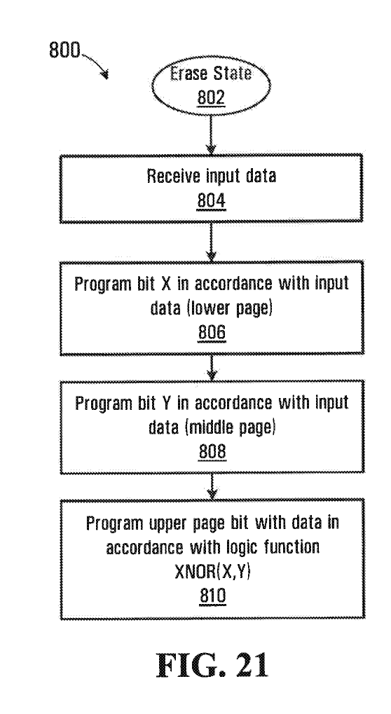

Referring to FIG. 21, a programming process for storing data in a memory cell in accordance with the embodiment shown in FIGS. 16-20 is shown generally at 800. The process 800 begins at block 802, where the memory cell is in the erase state. The process continues at block 804, with the memory cell receiving input data (in this embodiment two bits of data X and Y). The process then continues at block 806 where the input data bit X is programmed into the lower page. If the input data X is “1” then the threshold voltage Vₜ of the memory cell remains within the erase voltage range 682 (shown in FIG. 16), while if the input data is “0”, the threshold voltage Vₜ is moved into the program voltage range 692. At block 808, the data bit Y is then programmed into the middle page. If the data bit Y is “1”, and if following block 806 the threshold voltage Vₜ is still in the erase voltage range 682, then the threshold voltage remains within the erase voltage range. If following block 806, the threshold voltage is in the program voltage range 692, then the threshold voltage is moved up to the program voltage range 696.

If the input data bit Y is “0”, and if following block 806 the threshold voltage is still in the erase voltage range 682, then the threshold voltage is moved up to the program voltage range 688. If following block 806, the threshold voltage is in the program voltage range 692, then the threshold voltage remains within the program voltage range 692. The process 800 then continues at block 810, where the logical function of Eqn 7 is applied to the input data X and Y. If the result of the logical function is “1”, and if following block 808 the threshold voltage is still in the erase voltage range 682, then the threshold voltage remains within the erase voltage range. If following block 808, the threshold voltage is in the program voltage range 688, then the threshold voltage is moved up to the program voltage range 692. If following block 808, the threshold voltage is in the program voltage range 692, then the threshold voltage remains within the program voltage range 692. If following block 808, the threshold voltage is in the program voltage range 696, then the threshold voltage is moved up to the program voltage range 698.

If the result of the logical function is “0”, and if following block 808 the threshold voltage is still in the erase voltage range 682, then the threshold voltage is moved up to the program voltage range 686. If following block 808, the threshold voltage is in the program voltage range 688 then the threshold voltage remains within the program voltage range 688. If following block 808, the threshold voltage is in the program voltage range 692, then the threshold voltage is moved up to the program voltage range 694. If following block 808, the threshold voltage is in the program voltage range 696, then the threshold voltage remains in the program voltage range 696.

Advantageously, in this embodiment the upper page bit is used to store recovery data operable to associate two adjacently located program voltage ranges with a single memory state.

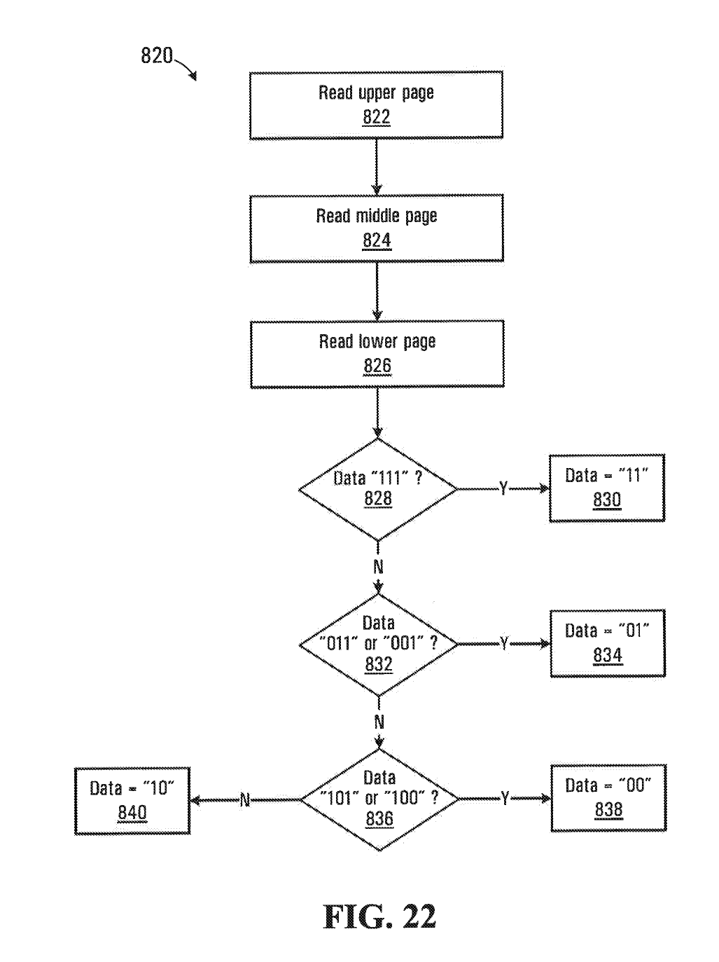

Referring to FIG. 22, a process for reading data from a memory cell in accordance with the embodiment shown in FIGS. 16-20 is shown generally at 820. The process 820 begins at block 822, where the upper page bit U is read by application of read voltages V₀, V₂, V₄, and V₆, to determine whether the U data bit is set to “1” or “0”. The process 820 then continues at block 824 where the middle page bit M is read by application of read voltages V₁, V₃, and V₅, to determine whether the M data bit is set to “1” or “0”. The process 820 then continues at block 826 where the lower page bit is read by applying a read voltage V₃, which is sufficient to unambiguously determine whether the data stored in the cell has a least significant bit of “0” or “1”.

The process then continues at block 828, where a determination is made as to whether the intermediate read data from the memory cell is “111”, in which case at block 830 the stored data XY (final read data) is thus “11”. If at block 828, the intermediate read data from the memory cell is not “111”, the process continues at block 832 where a determination is made as to whether the intermediate read data from the memory cell is “011” or “001”, in which case at block 834 the stored data XY (final read data) is thus “01”. If at block 832, the intermediate read data from the memory cell is not “011” or “001”, the process continues at block 836 where a determination is made as to whether the intermediate read data from the memory cell is “101” or “100”, in which case at block 838 the stored data XY (final read data) is thus “00”. If at block 836, the intermediate read data from the memory cell is not “101” or “100”, the process continues at block 840 and the stored data XY (final read data) is thus “10”.

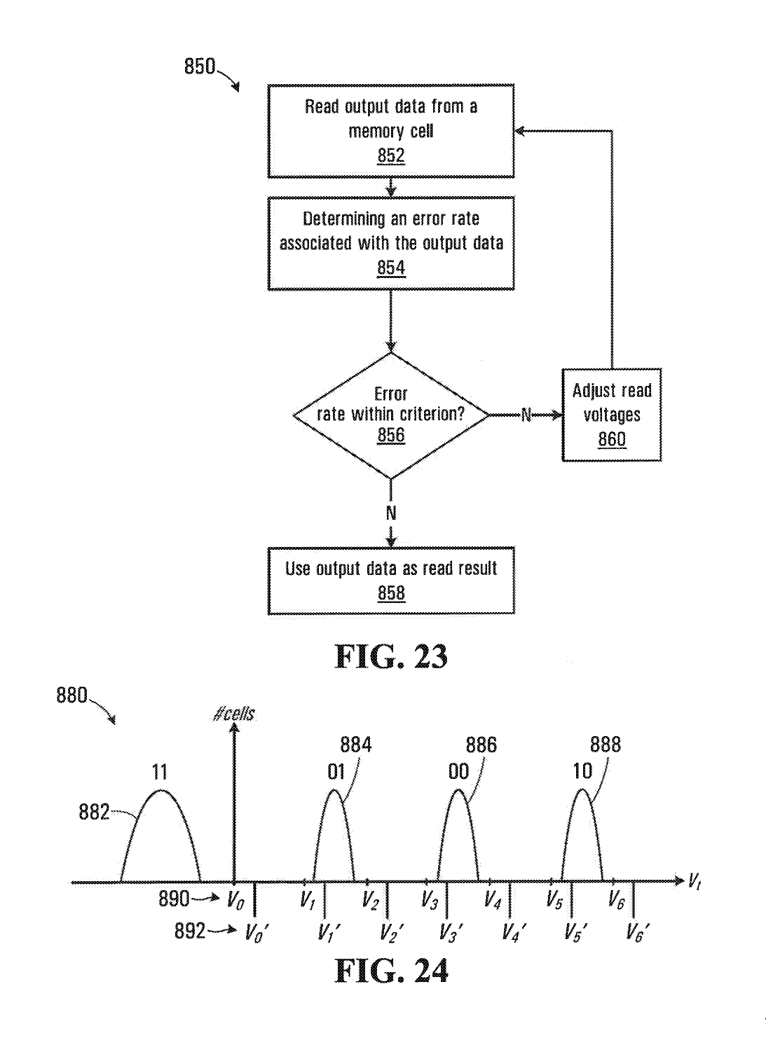

Referring to FIG. 23, a process for reading data from a memory cell in accordance with a further embodiment of the invention is shown generally at 850. In this embodiment, the memory cell has capacity to store three bits of data, but only two bits of data are stored in the cell. Referring to FIG. 24, voltage ranges for storing the two bits of data in the memory cell are shown generally at 880, and include an erase voltage range 882, and a plurality of program voltage ranges 884, 886, and 888. The programming of the memory cell 100 is performed generally in accordance with the embodiment shown in FIG. 16, where voltage ranges associated with storing a third highest order bit remain unused providing increased separation between the program voltage ranges. The memory cell is configured for read voltages 890 (i.e. V₀, V₁, V₂, V₃, V₄, V₅, and V₆) The process begins at block 852, where a read operation is performed on the memory cell to generate output data including two bits of data by applying read voltages V0, V2, and V4.

At block 854, an error rate associated with the output data is determined. As noted above, many non-volatile memories store error-correcting codes (ECC) and have an ECC engine that detects and attempts to correct errors in the read data. In one embodiment, an error rate for the output data may be determined by an ECC engine.

The process 850 then continues at block 856, where if the determined error rate is within an error rate criterion the process continues at block 858 and the output data is presumed valid and is used as the read result. If at block 856, the determined error rate exceeds the error rate criterion, then the process continues at block 860. At block 860 the plurality of read voltages are adjusted. Referring to FIG. 24, in this embodiment the read voltages 890 are shifted upwardly to define a new set of read voltages 892 (i.e. V₀′, V₁′, V₂′, V₃′, V₄′, V₅′, and V₆′).

The process 850 then returns to block 852 and blocks 852, 854 and 856 are repeated using the adjusted read voltages V₀′, V₂′, and V₄′ from the new set of read voltages 892. The process 850 continues until the error rate is within the criterion at block 856, or a pre-determined maximum adjustment to the read voltages is reached at block 860.

Alternatively, results from multiple read operations at different adjusted read voltages may be used as “soft-bits” in a low-density parity-check (LDPC) error correction scheme.

Advantageously, the process 850 provides a greater margin for disturbance to cells in a lower voltage range that could result in reading data in a next highest voltage range. While the embodiment of FIGS. 23 and 24 has been described with reference to storage of two bits in a cell having capacity to store three bits, the process may also be implemented for memory cells having capacity for storing two bits or more than three bits.

The above embodiments have generally been described with reference to storing a single bit of data in a memory cell having a configured capacity for storing two bits of data or storing two bits of data in a memory cell having a configured capacity for storing three bits of data. However, the above embodiments may be extended to memory cells having greater configured capacity for storing data, such as for example 4-bits of data.

The above disclosed embodiments provide processes for storing data in multi-bit per cell memories at lower density, but with improved endurance, lower read error rate, and improved data retention. The processes may be implemented at least in part by configuring an external controller, such as the external controller 309 shown in FIG. 4 through software, firmware, or dedicated hardware to implement the processes. The processes may also be implemented within the memory device 300 by configuring the memory device 300 to operate in a reduced number of bits per memory cell mode. Issuing a command from the memory controller 309 to program a register bit in the memory device 300, driving an input pin to a logic level, or employing a permanent fuse or masking operation set during manufacturing are all examples of how processes in accordance with embodiments of the invention may be enabled. The processes may be implemented only for specific blocks of memory or on a memory-wide basis.

While specific embodiments of the invention have been described and illustrated, such embodiments should be considered illustrative of the invention only and not as limiting the invention as construed in accordance with the accompanying claims.

What is claimed is:

1. A method for programming N bits in a non-volatile memory cell configured to store up to N+1 bits, where N is an integer greater than zero, the method comprising;
a) programming N bits of data in the non-volatile memory cell; and
b) programming an additional bit of data that is a logical function of the N bits of data in the non-volatile memory cell, and
the non-volatile memory cell being configured to provide 2^{N+1} threshold voltage ranges for bit storage and, in accordance with the logical function: i) a first set of 2^{N} threshold voltage ranges of the 2^{N+1} threshold voltage ranges are used to store the N bits of data; and ii) a remaining second set of 2^{N} threshold voltage ranges alternating with the first set are unused.

2. The method of claim 1 wherein N is one, and the 2^{N+1} threshold voltage ranges include an erase voltage range and first, second and third program voltage ranges, the first program voltage range being higher than and adjacent to the erase voltage range, the second program voltage range being higher than and adjacent to the first program voltage range, and the third program voltage range being higher than and adjacent to the second program voltage range, and the first set of 2^{N} threshold voltage ranges comprising the erase voltage range and the second program voltage range, and the remaining set of 2^{N} threshold voltage ranges comprising the first program voltage range and the third program voltage range.

3. The method of claim 1 wherein N is one, and the programming of the N bits of data in the non-volatile memory cell comprises carrying out lower page programming, and the programming of the additional bit of data comprises upper page programming.

4. The method of claim 1 wherein N is two, and the programming of the N bits of data in the non-volatile memory cell comprises carrying out lower and middle page programming, and the programming of the additional bit of data comprises upper page programming.

5. The method of claim 4 wherein the logical function of the N bits of data in the non-volatile memory cell is an exclusive NOR function of lower and middle page data.

6. The method of claim 1 wherein the programming of the N bits of data in the non-volatile memory cell includes carrying out lower page programming, and a temporary program voltage range is employed when data “1” is programmed during the lower page programming.

7. A memory device comprising:
a plurality of non-volatile memory cells, each non-volatile memory cell of the non-volatile memory cells being configured to provide 2^{N+1} threshold voltage ranges for bit storage, where N is an integer greater than zero, and the 2^{N+1} threshold voltage ranges including an erase voltage range and a plurality of program voltage ranges, the plurality of program voltage ranges including a first program voltage range adjacent to the erase voltage range and a plurality of higher program voltage ranges, and the non-volatile memory cell being configured to store up to N+1 bits, and
the memory device being configured to:
a) program N bits of data in the non-volatile memory cell; and
b) program an additional bit of data that is a logical function of the N bits of data in the non-volatile memory cell, and
in accordance with the logical function: i) a first set of 2^{N} threshold voltage ranges of the 2^{N+1} threshold voltage ranges are used to store the N bits of data; and ii) a remaining second set of 2^{N} threshold voltage ranges alternating with the first set are unused.

8. The memory device of claim 7 wherein N is one, and the 2^{N+1} threshold voltage ranges include an erase voltage range and first, second and third program voltage ranges, the first program voltage range being higher than and adjacent to the erase voltage range, the second program voltage range being higher than and adjacent to the first program voltage range, and the third program voltage range being higher than and adjacent to the second program voltage range, and the first set of 2^{N} threshold voltage ranges comprising the erase voltage range and the second program voltage range, and the remaining set of 2^{N} threshold voltage ranges comprising the first program voltage range and the third program voltage range.

9. The memory device of claim 7 wherein N is one, and a carrying out of lower page programming is included when the memory device programs the N bits of data in the non-volatile memory cell, and upper page programming is included when the memory device programs the additional bit of data.

10. The memory device of claim 7 wherein N is two, and a carrying out of lower and middle page programming is included when the memory device programs the N bits of data in the non-volatile memory cell, and upper page programming is included when the memory device programs the additional bit of data.

11. The memory device of claim 10 wherein the logical function of the N bits of data in the non-volatile memory cell is an exclusive NOR function of lower and middle page data.

12. The memory device of claim 7 wherein a carrying out of lower page programming is included when the memory device programs the N bits of data in the non-volatile memory cell, and a temporary program voltage range is employed when data “1” is programmed during the lower page programming.

13. The memory device of claim 7 wherein the plurality of non-volatile memory cells are NAND flash memory cells.

14. A method carried out in a memory device having a plurality of non-volatile memory cells, and each non-volatile memory cell of the non-volatile memory cells having multiple memory states being defined by respective threshold voltage ranges including an erase voltage range, a first program voltage range, a second program voltage range and a third program voltage range, the first program voltage range being adjacent to the erase voltage range and the second program voltage range being in-between the first and third program voltage ranges, and the method comprising:
when operating the non-volatile memory cell in a two bit storage mode, storing two bits of data by:
carrying out a first stage programming to program a first of two bits of data; and
carrying out a second stage programming to program a second of the two bits of data; and
when operating the non-volatile memory cell in a one bit storage mode, storing a single bit of data by:
carrying out both the first and second stage programmings in a manner that raises a cell threshold voltage twice to reach the second program voltage range if the single bit of data is data “1” and keeping the cell threshold voltage at the erase voltage range if the single bit of data is data “0”.

15. The method of claim 14 wherein the first stage programming is lower page programming and the second stage programming is upper page programming.

16. The method of claim 14 wherein the non-volatile memory cell is a NAND flash memory cell.

17. A method carried out in a system that includes a non-volatile memory device, the method comprising:
a) sequentially reading N bits of intermediate read data from a non-volatile memory cell of the non-volatile memory device, where N is an integer greater than one;
b) providing the N bits of the intermediate read data to N inputs of a logic circuit; and
c) outputting N−1 bits of final read data from N−1 outputs of the logic circuit.

18. The method as claimed in claim 17 wherein N is two.

19. The method as claimed in claim 18 wherein the final read data outputted from the logic circuit is ‘1’ only when the intermediate read data is ‘11’.

20. The method as claimed in claim 17 wherein N is three.

21. The method as claimed in claim 20 wherein the final read data outputted from the logic circuit is: a) ‘11’ only when the intermediate read data is ‘111’; b) ‘01’ only when the intermediate read data is ‘011’ or ‘001’; and c) ‘00’ only when the intermediate read data is ‘101’ or ‘100’.

22. A system comprising:
a memory device, the memory device including a plurality of non-volatile memory cells, and the memory device being configured to sequentially read N bits of intermediate read data from at least one of the non-volatile memory cells, where N is an integer greater than one; and
an external controller that includes a logic circuit, the external controller configured to:
a) receive the N bits of intermediate read data from the memory device;
b) provide the N bits of the intermediate read data to N inputs of the logic circuit; and
c) output N−1 bits of final read data from N−1 outputs of the logic circuit.

23. The system as claimed in claim 22 wherein N is two.

24. The system as claimed in claim 23 wherein the final read data is ‘1’ only when the intermediate read data is ‘11’.

25. The system as claimed in claim 22 wherein N is three.

26. The system as claimed in claim 25 wherein the final read data is: a) ‘11’ only when the intermediate read data is ‘111’; b) ‘01’ only when the intermediate read data is ‘011’ or ‘001’; and c) ‘00’ only when the intermediate read data is ‘101’ or ‘100’.

27. A memory device comprising:
a memory array including a plurality of non-volatile memory cells; and
a logic circuit communicatively coupled to the memory array, and
the memory device configured to:
sequentially read N bits of intermediate read data from at least one of the non-volatile memory cells, where N is an integer greater than one;
input the N bits of the intermediate read data to N inputs of the logic circuit; and
output N−1 bits of final read data from N−1 outputs of the logic circuit.

28. The memory device as claimed in claim 27 wherein N is two.

29. The memory device as claimed in claim 28 wherein the final read data is ‘1’ only when the intermediate read data is ‘11’.

30. The memory device as claimed in claim 27 wherein N is three.

31. The memory device as claimed in claim 30 wherein the final read data is: a) ‘11’ only when the intermediate read data is ‘111’; b) ‘01’ only when the intermediate read data is ‘011’ or ‘001’; and c) ‘00’ only when the intermediate read data is ‘101’ or ‘100’.
